(19) United States
(12) Patent Application Publication
(10) Pub. No.: US 2008/0203432 A1
(43) Pub. Date: Aug. 28, 2008

(54) SEMICONDUCTOR DEVICE AND METHOD FOR FABRICATING THE SAME

(75) Inventor: Seong-Yeon KIM, Ichon-shi (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Ichon-shi (KR)

(21) Appl. No.: 11/951,212

(22) Filed: Dec. 5, 2007

(30) Foreign Application Priority Data
Feb. 23, 2007 (KR) 10-2007-0018341

(51) Int. Cl. H01L 29/94; H01L 21/336

(52) U.S. Cl. 257/192; 438/285; 257/E21.409; 257/E29.345

(57) ABSTRACT

A transistor including a gate insulation layer, a gate, and source/drain regions, the transistor comprising a semiconductor layer formed under the gate insulation layer for use as a channel region in a substrate, wherein the semiconductor layer is formed of a material having a lower bandgap than silicon.

### CROSS-REFERENCE TO RELATED APPLICATIONS

The present invention claims priority of Korean patent application number 10-2007-0018341, filed on Feb. 23, 2007, which is incorporated by reference in its entirety.

### BACKGROUND OF THE INVENTION

The present invention relates to a semiconductor device, and more particularly, to a transistor of a semiconductor device and a method for fabricating the same.

As it is well known, semiconductor devices, particularly complementary metal oxide semiconductor (CMOS) devices, are integrally formed with a plurality of N-channel MOS (NMOS) transistors and a plurality of P-channel MOS (PMOS) transistors. To miniaturize an integrated circuit (IC), it is necessary to develop higher integration while electrical properties of devices, such as driving speed, are not deteriorated.

FIG. 1 illustrates a cross-sectional view of a typical transistor in a semiconductor device. Referring to FIG. 1, an isolation layer 12 is formed in a predetermined region of a substrate 11 to define an active region. The isolation layer 12 is formed by a shallow trench isolation (STI) process. A gate insulation layer 15 is formed on the active region and a gate electrode layer 16 is formed on the gate insulation layer 15. A channel region 14 is formed under a surface of the substrate 11 below the gate insulation layer 15. The channel region 14 in the substrate 11 is typically doped with impurities so as to adjust a threshold voltage. Source/drain regions 13 are aligned with both edges of the gate electrode 16 to be in contact with the channel region 14. The source/drain regions 13 are typically formed through an ion implantation and an annealing process for impurities activation.

As semiconductor devices become highly integrated, a channel length gradually decreases, which reduces a distance between the source region and the drain region. Hence, this leads to a short channel effect where the threshold voltage drops rapidly. The decrease in threshold voltage causes leakage current to be increased in an atmospheric state and a punch-through to occur between the source region and the drain region, thus degrading device characteristics.

Moreover, in the typical semiconductor device of FIG. 1, the channel region 14 and the source/drain regions 13 of the transistor are all formed of silicon. The silicon is an indirect transference material which exhibits poorer carrier mobility than a direct transference material. The carrier mobility in the channel region of the semiconductor device is considered important because it is strongly correlated with a driving speed of the semiconductor device.

To improve the carrier mobility, generally, silicon germanium (SiGe) is employed in the channel region 14 in the semiconductor device. However, the silicon germanium is not used to improve the carrier mobility in an NMOS transistor, which uses electrons as carriers, because the silicon germanium has a conduction band difference of 0.05 eV which is not much greater than that of the silicon.

Accordingly, to increase the driving speed of the semiconductor device, it is necessary to improve the carrier mobility in the channel region of the semiconductor device.

### SUMMARY OF THE INVENTION

The present invention relates to a transistor in a semiconductor device which is adapted to improve a driving speed of a device by increasing carrier mobility in a channel of a highly integrated and downsized transistor, and a method for fabricating the same.

In accordance with an aspect of the present invention, there is provided a transistor, the transistor including a gate insulation layer, a gate, and source/drain regions, the transistor comprising a semiconductor layer formed under the gate insulation layer to use as a channel region in a substrate, wherein the semiconductor layer is formed of a material having a lower bandgap than silicon.

In accordance with another aspect of the present invention, there is provided a method for fabricating a transistor, the method comprising: selectively etching a substrate to form a first recess for a channel region and a second recess for source/drain regions; forming a semiconductor layer having a lower bandgap than silicon in the first recess; growing an epitaxial layer in the second recess; and forming a gate insulation layer and a gate over the semiconductor layer.

In accordance with further another aspect of the present invention, there is provided a method for fabricating a semiconductor, the semiconductor device comprising: providing a substrate having an isolation layer; selectively etching the substrate to form a first recess having a depth for a channel region and a second recess for source/drain regions; forming a semiconductor layer having a lower bandgap than silicon in a portion of the first recess and having a depth smaller than the depth for the channel region; growing an epitaxial layer filling the second recess and a remaining portion of the first recess; and forming a gate structure over the channel region.

### BRIEF DESCRIPTION OF THE DRAWINGS

FIG. 1 illustrates a cross-sectional view of a typical transistor.

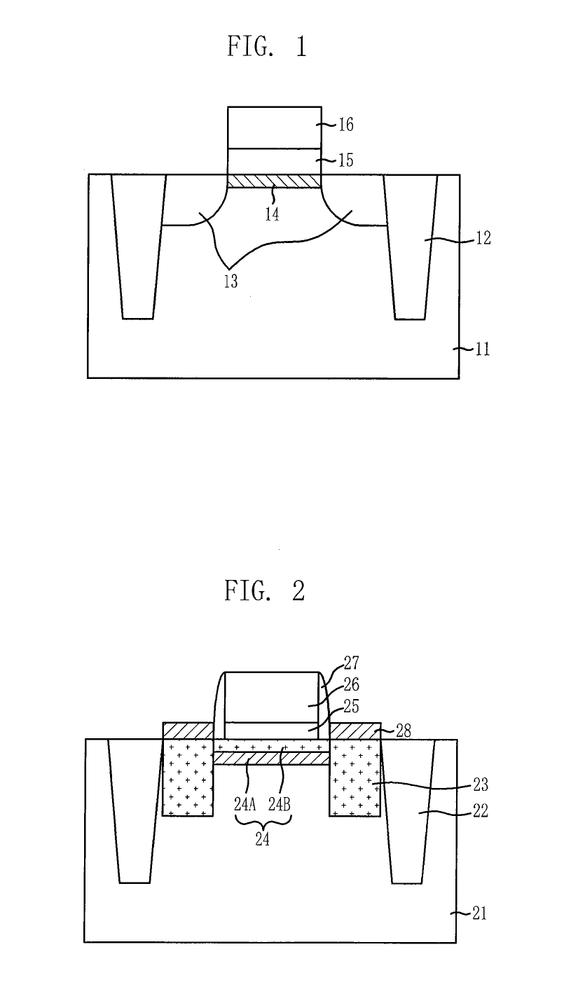

FIG. 2 illustrates a cross-sectional view of a transistor in accordance with an embodiment of the present invention.

FIG. 3 illustrates a heterojunction band diagram of silicon-indium antimonide (Si—InSb).

FIG. 4 illustrates a heterojunction band diagram of silicon-indium arsenide (Si—InAs).

FIGS. 5A to 5E illustrate a method for fabricating the transistor in accordance with an embodiment of the present invention.

### DESCRIPTION OF SPECIFIC EMBODIMENTS

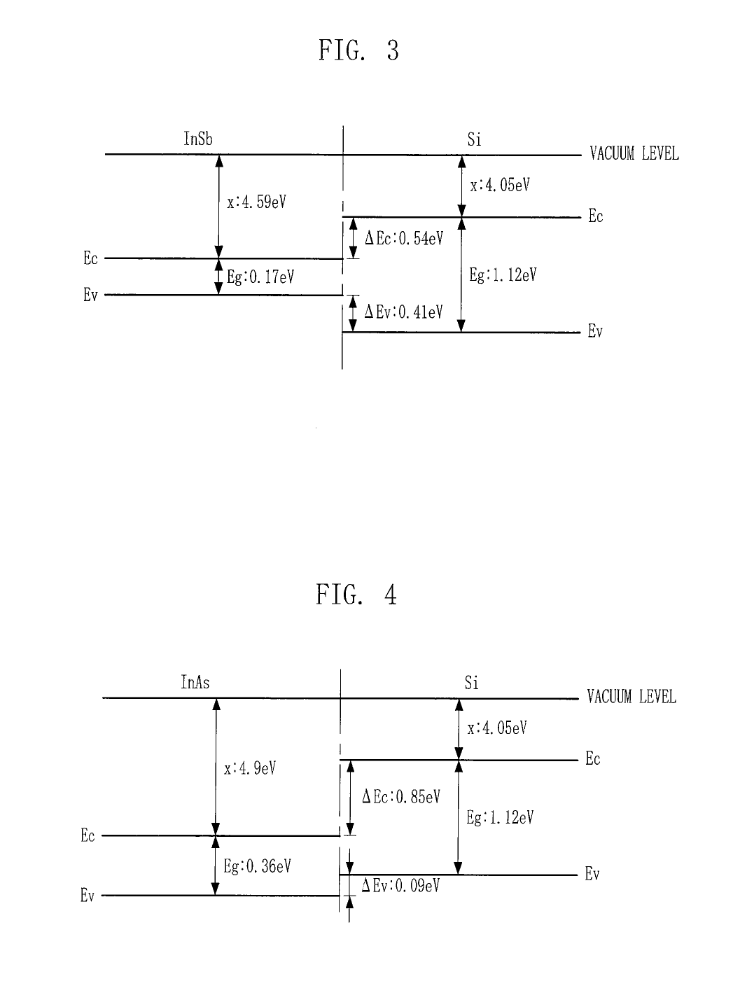

FIG. 2 illustrates a cross-sectional view of a transistor in accordance with an embodiment of the present invention. Referring to FIG. 2, a channel layer 24 has a stacked structure of a first channel layer 24A and a second channel layer 24B. The first channel layer 24A includes indium antimonide (InSb) or indium arsenide (InAs), or both and the second channel layer 24B includes a silicon (Si) layer. The channel layer 24 is formed under a gate insulation layer 25 and in a recessed region of a substrate 21 having an isolation layer 22.

Indium antimonide (InSb) is a material having a direct bandgap so that it has higher carrier mobility than silicon having an indirect bandgap. Further, the InSb has a narrow bandgap and very high electron mobility of approximately 80,000 cm²/v-s. Therefore, when the indium antimonide is applied to the channel, it is possible to enhance the current drivability of the transistor. The carrier mobility is strongly correlated with the driving speed of the device.

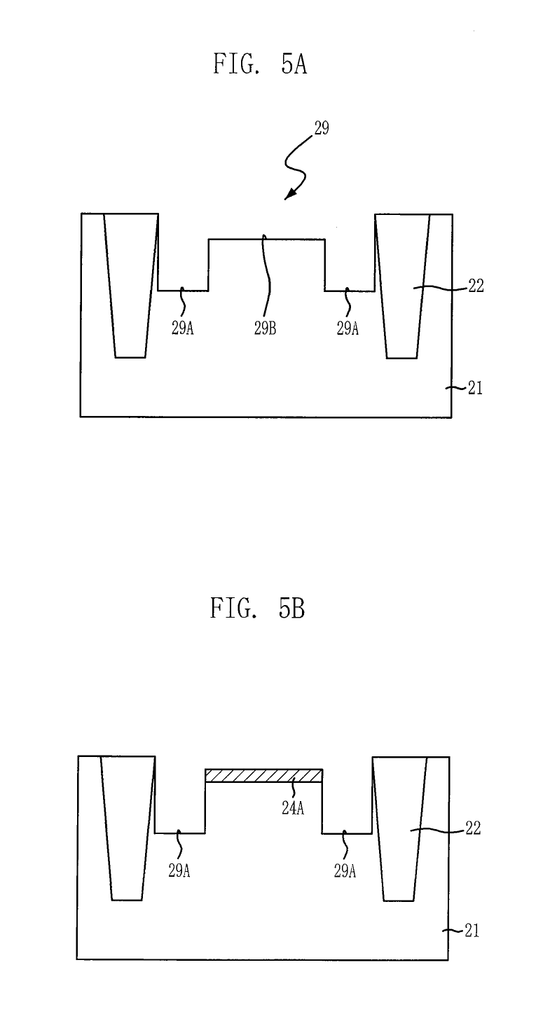

FIG. 3 illustrates a heterojunction band diagram of silicon-indium antimonide (Si—InSb). An indium antimonide (InSb) has an electron affinity (χ) of 4.59 eV while silicon has an electron affinity of 4.05 eV. Thus, a bandgap (Eg) of the InSb is nearly half of the bandgap (Eg) of silicon so that an energy band of the InSb is positioned in the middle of the bandgap of the silicon when the InSb is connected to the silicon. Since the bandgap (Eg) of the InSb is 0.17 eV, a conduction band difference (ΔEc) between the InSb and the silicon and a valence band difference (ΔEv) between the InSb and the silicon increase to 0.54 eV and 0.41 eV, respectively, which makes it possible to improve current drivability in both NMOS and PMOS transistors.

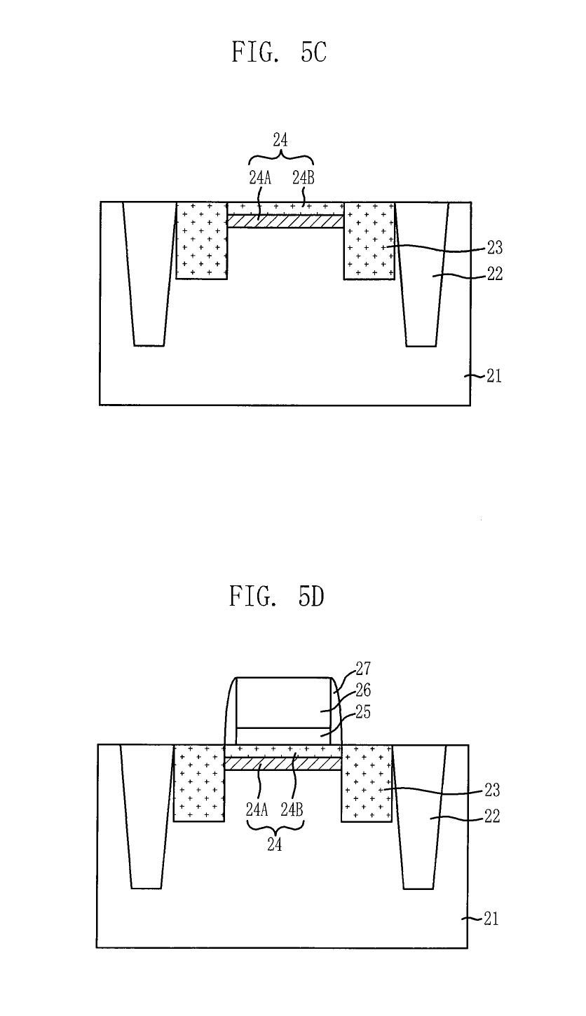

Alternatively, the first channel layer 24A may be formed of an indium arsenide (InAs) instead of the InSb. When the InAs is used as the first channel layer 24A, there is no improvement in PMOS transistors but there is great improvement in NMOS transistors, which will be more fully described with reference to FIG. 4.

FIG. 4 illustrates a heterojunction band diagram of silicon-indium arsenide (Si—InAs). The indium arsenide (InAs) has an electron affinity (χ) of 4.90 eV so that an energy band of the InAs is positioned near the valence band (Ev) of the silicon. In this case, an energy band gap (Eg) of the InAs is 0.36 eV in a silicon-indium arsenide junction. Therefore, a valence band difference (ΔEv) between the silicon and the InAs is 0.09 eV so that hole current is rarely improved. On the contrary, an electron current is noticeably improved because a conduction band difference (ΔEc) between the silicon and the InAs is 0.85 eV which is greater than the conduction band difference (ΔEc) of 0.54 eV between the silicon and the InSb. Hence, when the InAs is used as the first channel layer 24A, it is possible to obtain NMOS transistors with higher current drivability.

The embodiment of the present invention provides another advantageous merit by providing the silicon layer 24B between the gate insulation layer 25 and the indium antimonide layer 24A. When the transistor is formed by using the silicon-indium antimonide heterojunction structure, a threshold voltage can be controlled by merely doping on the silicon layer 24B without doping on the indium antimonide layer 24A. Two-dimensional (2-D) electron gas is formed on the indium antimonide layer 24A by using an energy level difference between the InSb and the silicon, whereby the undoped indium antimonide layer 24A has much higher carrier mobility. In virtue of the silicon layer 24B, the gate insulation layer 25 may be formed of silicon oxide (SiO₂) with good quality by thermally oxidizing the silicon layer 24B. Furthermore, the gate insulation layer 25 may be formed by forming a silicon oxide layer over the silicon layer 24B for the channel region.

Referring to FIG. 2, in the transistor in accordance with the embodiment, the source/drain regions 23 are formed of epitaxial silicon grown in the recess region of the substrate 21. When the source/drain regions 23 are formed by the epitaxial silicon layer in the recess, it is unnecessary to perform a rapid temperature annealing (RTA) process, thus preventing the increase in leakage current caused by diffusion of impurities in the source/drain regions 23 into the channel region 24.

When the impurities are doped into the source/drain regions 23 formed by the epitaxial silicon and without the RTA process, contact resistance may be increased. Therefore, a conductive layer 28 is formed over the source/drain regions 23 formed by the epitaxial silicon so as to improve the contact resistance. The conductive layer 28 includes an indium antimonide contact layer or an indium arsenide contact layer, or both. An insulation sidewall spacer 27 is formed on sidewalls of a gate 26.

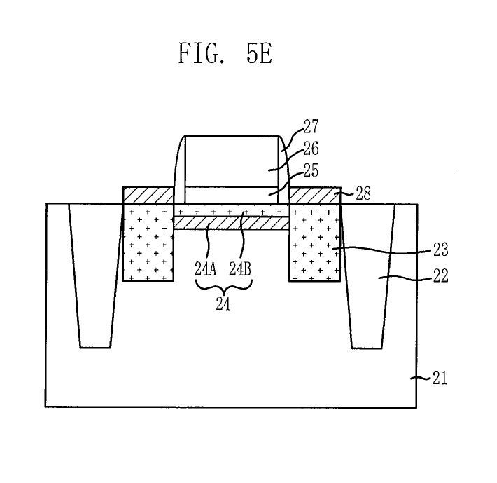

FIGS. 5A to 5E illustrate a method for fabricating the transistor of FIG. 2.

Referring to FIG. 5A, an isolation layer 22 is formed in a substrate 21. A first portion of the substrate 21 where source/drain regions will be formed (through masking and etching processes) and a second portion of the substrate 21 where a channel will be formed are etched to form a recess 29. A first etch depth of the first portion is approximately 300 Å and a second etch depth of the second portion is approximately 100 Å. However, the first and second etch depths may be changed to control the electrical properties of a transistor. The substrate 21 is etched through a dry etching process using mixed gas of methane (CH₄), difluoromethane (CHF₃), oxygen (O₂). Since the first depth of a first recess 29A for a channel region differs from that of a second recess 29B for the source/drain regions, the masking and etching processes are performed several times.

Referring to FIG. 5B, a first channel layer 24A is formed over the second recess 29B of the channel region. The first channel layer 24A includes a semiconductor layer. The semiconductor layer includes an indium antimonide (InSb) or an indium arsenide (InAs), or both. It is possible to form the indium antimonide layer 24A merely over the second recess 29B of the channel region using a variety of well-known techniques. The indium antimonide layer 24A has a depth smaller than the second depth of the second recess 29B.

Referring to FIG. 5C, a second channel layer 24B for the channel is formed over the indium antimonide layer 24A and a source/drain region 23 is formed in the first recess 29A. A channel layer 24 has a stacked structure of a first channel layer 24A and a second channel layer 24B. The second channel layer 24B and the source/drain region 23 include a silicon layer. The silicon layer 24B and the source/drain region 23 are formed by using a selective epitaxial growth (SEG) process. Specifically, a silicon growth where the SEG process is performed with a silicon source gas and a doping gas at a temperature ranging from approximately 500° C. to approximately 1000° C., at a pressure ranging from approximately 1 mTorr to approximately 1000 mTorr and at an impurity concentration ranging from approximately 1×10¹⁴ atoms/cm³ to approximately 1×10²⁰ atoms/cm³ in a low pressure chemical vapor deposition (LPCVD) apparatus. The silicon source gas includes one of a silane (SiH₄), a Si₃H₄ gas, a 3-[(2,5-dichlorophenyl)carbamoyl]propanoic acid (DCS) gas or a combination thereof, and the doping gas includes one of a phosphane (PH₃) gas, an arsane (AsH₃) gas or B₂H₆.

A chemical mechanical polishing (CMP) is performed to planarize a height difference, resulting from the silicon growth between the channel and the source/drain regions. Although the silicon layer 24B and the source/drain region 23 are formed at the same time in accordance with the embodiment of the present invention, it is possible for the silicon layer 24B and the source/drain region 23 to be separately formed in accordance with another embodiment of the present invention.

Referring to FIG. 5D, a gate insulation layer 25, a gate electrode layer 26 and a gate spacer layer 27 are formed in sequence. The gate insulation layer 25 is formed by thermally oxidizing the silicon layer 24B. Furthermore, the gate insulation layer 25 may be formed by forming a silicon oxide layer over the silicon layer 24B for the channel region. The gate electrode layer 26 is formed on the gate insulation layer 25. The gate electrode layer 26 includes a polysilicon doped with impurities or a polysilicon subsequently doped with P-type or N-type impurities. Furthermore, the gate electrode layer 25 also includes a metal-silicide layer or a metal material layer.

Referring to FIG. 5E, the conductive layer 28 is formed to improve a contact resistance over the source/drain regions 23. The conductive layer 28 includes the indium antimonide contact layer or the indium arsenide contact layer, or both.

Although the indium antimonide layer 24A is used as a heterojunction material for the channel region in accordance with the embodiment of the present invention, the indium arsenide (InAs) is also available, wherein the indium arsenide is one of Group III-V compound semiconductors similar to indium antimonide, and has a direct transference bandgap and a narrow bandgap. Furthermore, both of them are also available.

In accordance with the present invention, a material with high carrier mobility, such as InSb and InAs, is applied to a channel region of a transistor to improve a driving speed of a device.

Furthermore, since a channel layer has a stacked structure of doped silicon and undoped InSb or InAs, it is possible to control a threshold voltage and improve carrier mobility as well. In the meantime, a gate insulation layer can be formed of a silicon oxide (SiO₂) layer with good quality. Moreover, a doped epitaxial layer is used as source/drain regions without a RTA process and InSb or InAs is then formed thereon, thus making it possible to prevent impurities of the source/drain regions from diffusing to the outside, that is, from diffusing to the channel region, and to improve the contact resistance.

While the present invention has been described with respect to the specific embodiments, the above embodiments of the present invention are illustrative and not limitative. It will be apparent to those skilled in the art that various changes and modifications may be made without departing from the spirit and scope of the invention as defined in the following claims.

What is claimed is:

1. A transistor including a gate insulation layer, a gate, and source/drain regions, the transistor comprising a semiconductor layer formed under the gate insulation layer for use as a channel region in a substrate, wherein the semiconductor layer is formed of a material having a lower bandgap than silicon.

2. The transistor of claim 1, further comprising a silicon layer formed between the gate insulation layer and the semiconductor layer.

3. The transistor of claim 2, wherein the silicon layer includes an epitaxial layer.

4. The transistor of claim 2, wherein the gate insulation layer includes a thermally oxidizing silicon oxide layer.

5. The transistor of claim 1, wherein the semiconductor layer includes one of Group III-V compound semiconductors.

6. The transistor of claim 5, wherein the semiconductor layer includes an indium antimonide (InSb) or an indium arsenide (InAs), or both.

7. The transistor of claim 1, wherein the source/drain regions include an epitaxial silicon layer.

8. The transistor of claim 1, further comprising an indium antimonide contact layer or an indium arsenide contact layer, or both, formed over the source/drain regions.

9. The transistor of claim 2, wherein the semiconductor layer and the silicon layer formed over the semiconductor layer are formed in the substrate.

10. The transistor of claim 7, wherein the epitaxial silicon layer of the source/drain regions is formed in the substrate.

11. The transistor of claim 2, wherein the semiconductor layer is undoped with impurities and the silicon layer is doped with impurities to control a threshold voltage.

12. A method for fabricating a transistor, the method comprising:
selectively etching a substrate to form a first recess for a channel region and a second recess for source/drain regions;
forming a semiconductor layer having a lower bandgap than silicon in the first recess;
growing an epitaxial layer in the second recess; and
forming a gate insulation layer and a gate over the semiconductor layer.

13. The method of claim 12, further comprising forming a silicon layer for the channel region between the semiconductor layer and the gate insulation layer.

14. The method of claim 13, wherein the gate insulation layer is formed by thermally oxidizing the silicon layer for the channel region.

15. The method of claim 13, wherein the silicon layer is formed by an epitaxial growth.

16. The method of claim 12, wherein the semiconductor layer includes an InSb or an InAs, or both.

17. The method of claim 12, wherein the epitaxial layer includes a silicon layer.

18. The method of claim 12, further comprising forming an indium antimonide or an indium arsenide contact layer, or both, over the epitaxial layer.

19. The method of claim 13, further comprising doping impurities into the silicon layer in the first recess to control a threshold voltage.

20. The method of claim 16, wherein the semiconductor layer is undoped with impurities.

21. A semiconductor device, comprising:
providing a substrate having an isolation layer;
selectively etching the substrate to form a first recess having a depth for a channel region and a second recess for source/drain regions;
forming a semiconductor layer having a lower bandgap than silicon in a portion of the first recess and having a depth smaller than the depth for the channel region;
growing an epitaxial layer filling the second recess and a remaining portion of the first recess; and
forming a gate structure over the channel region.
